(19) United States
(12) Patent Application Publication
(10) Pub. No.: US 2021/0351192 A1
(43) Pub. Date: Nov. 11, 2021

(54) ONE-TIME PROGRAMMABLE DEVICE WITH ANTIFUSE

(71) Applicant: QUALCOMM Incorporated, San Diego, CA (US)

(72) Inventors: Mishel MATLOUBIAN, San Diego, CA (US); Taehun KWON, San Diego, CA (US); Gang LIN, San Diego, CA (US)

(21) Appl. No.: 16/869,829

(22) Filed: May 8, 2020

(51) Int. Cl. H01L 27/112; H01L 29/78; G11C 17/16

(52) U.S. Cl. CPC H01L 27/11206; G11C 17/165; H01L 29/7833

(57) ABSTRACT

Certain aspects of the present disclosure generally relate to a one-time programmable (OTP) device including an antifuse device. The antifuse device generally includes a first active region, a second active region, a channel region disposed between the first active region and the second active region, a gate region disposed above the channel region, and a first set of lightly doped drain (LDD) extension regions extending partially across the channel region from the first active region and the second active region and extending into a portion of the channel region underneath the gate region. The first set of LDD extension regions have a same dopant type as the gate region and at least one of the first active region or the second active region.

### TECHNICAL FIELD

Certain aspects of the present disclosure generally relate to electronic components and, more particularly, to an improved one-time programmable device including an antifuse device.

### BACKGROUND

Integrated circuits (ICs) are interconnected networks of electrical components fabricated on a common foundation called a substrate. The substrate is typically a wafer of semiconductor material, such as silicon (Si). Various fabrication techniques, such as layering, doping, masking, and etching, are used to build millions of resistors, transistors, and other electrical components on the wafer. The components are then wired together, or interconnected, to define a specific electrical circuit, such as a processor or a memory device.

Fusible elements are employed in integrated circuits to permit changes in the configuration of the integrated circuits after fabrication. For example, fusible elements may be used to replace defective circuits with redundant circuits. As another example, fusible elements may be used to create one-time programmable (OTP) or multi-time programmable (MTP) memory circuits. Individual memory cells of an OTP memory cell may be written to once in order to create read-only memory modules that cannot be easily altered and/or are secure.

One type of fusible element is an antifuse. Fabricated as an open circuit, an antifuse comprises two conductive terminals separated by an insulator (e.g., a dielectric material). The antifuse is programmed by applying a relatively high voltage (e.g., 7.5 V) across its terminals to rupture the insulator and form an electrical path between the terminals. A gate dielectric antifuse may be a metal-oxide-semiconductor field-effect transistor (MOSFET) that is designed such that the gate oxide located between the transistor's gate terminal and the body—or between the gate terminal and the source/drain terminal—breaks down (i.e., ruptures) after a sufficiently high voltage is applied.

### SUMMARY

Certain aspects of the present disclosure generally relate to a one-time programmable (OTP) device having an antifuse transistor device including at least a first set of lightly doped drain (LDD) extension regions extending into a channel between a first active region of the antifuse device and a second active region of the antifuse device. The first set of LDD extension regions may be formed in the antifuse transistor device such that an ohmic contact is formed between a gate region of the antifuse transistor device and at least one of the first active region or the second active region when the antifuse transistor device is programmed.

Certain aspects of the present disclosure are generally directed to a one-time programmable (OTP) device. The OTP device generally includes a word line transistor device comprising: a first active region, a second active region, a first channel region disposed between the first active region and the second active region, a first gate region disposed above the first channel region, and a first set of lightly doped drain (LDD) extension regions extending partially across the first channel region from the first active region and the second active region. Additionally, the OTP device generally includes an antifuse transistor device coupled in series with the word line transistor device, the antifuse transistor device comprising: a third active region, a fourth active region, a second channel region disposed between the third active region and the fourth active region, a second gate region disposed above the second channel region, and a second set of LDD extension regions extending partially across the second channel region from the third active region and the fourth active region, wherein the first set of LDD extension regions of the word line transistor device and the second set of LDD extension regions of the antifuse transistor device comprise approximately the same dopant concentrations.

Certain aspects of the present disclosure are generally directed to a method for fabricating a one-time programmable (OTP) device. The method involves forming a word line transistor device and forming an antifuse transistor device coupled in series with the word line transistor device. Forming the word line transistor device generally includes forming a first active region and a second active region, such that a first channel region is disposed between the first active region and the second active region, forming a first gate region disposed above the first channel region, and forming a first set of lightly doped drain (LDD) extension regions extending partially across the first channel region from the first active region and the second active region. Forming the antifuse transistor device generally includes forming a third active region and a fourth active region, such that a second channel region is disposed between the third active region and the fourth active region, forming a second gate region disposed above the second channel region, and forming a second set of LDD extension regions extending partially across the second channel region from the third active region and the fourth active region, wherein the first set of LDD extension regions of the word line transistor device and the second set of LDD extension regions of the antifuse transistor device comprise approximately the same dopant concentrations.

Certain aspects of the present disclosure are generally directed to an antifuse device. The antifuse device generally includes a first active region, a second active region, a channel region disposed between the first active region and the second active region, a gate region disposed above the channel region, and a first set of LDD extension regions extending partially across the channel region from the first active region and the second active region and extending into a portion of the channel region underneath the gate region, wherein the first set of LDD extension regions have a same dopant type as the gate region and at least one of the first active region or the second active region.

Certain aspects of the present disclosure are generally directed to a method for fabricating an antifuse device. The method generally includes forming a first active region and a second active region, such that a channel region is disposed between the first active region and the second active region, forming a gate region disposed above the channel region, and forming a first set of LDD extension regions extending partially across the channel region from the first active region and the second active region and extending into a portion of the channel region underneath the gate region, wherein the first set of LDD extension regions have a same dopant type as the gate region and at least one of the first active region or the second active region.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates a cross-sectional view of a conventional one-time programmable (OTP) device.

FIG. 2A illustrates an OTP including an antifuse device with core lightly doped drain (LDD) regions, in accordance with certain aspects presented herein.

FIG. 2B illustrates an OTP including an antifuse device with core LDD regions and input/output (I/O) LDD regions, in accordance with certain aspects presented herein.

FIG. 3 is a flow diagram illustrating example operations for fabricating an OTP device, in accordance with certain aspects of the present disclosure.

FIG. 4 is a flow diagram illustrating example operations for fabricating an antifuse device, in accordance with certain aspects of the present disclosure.

### DETAILED DESCRIPTION

Certain aspects of the present disclosure are generally directed to a one-time programmable (OTP) device including an antifuse device. The antifuse device generally includes a first active region, a second active region, a channel region disposed between the first active region and the second active region, and a gate region disposed above the channel region. Additionally, the antifuse device may include at least a first set of lightly doped drain (LDD) extension regions, extending partially across the channel region from the first active region and the second active region and extending into a portion of the channel region underneath the gate region. In some cases, the first set of LDD extension regions have a same dopant type as the gate region and at least one of the first active region or the second active region. According to aspects, the first set of LDD extension regions may provide ohmic contact between the gate region and at least one of the first active region or the second active region when the antifuse device is programmed This ohmic contact may increase the read current compared to other antifuse devices with a p-n junction, thereby improving read operations associated with the antifuse device in the OTP device.

For certain aspects, the OTP device may also include a word line device. In this case, the doping in the LDD regions may be the same for both the word line device and the antifuse device.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Certain terminology may also be used in the following description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

### Example Conventional One-Time Programmable Device

As noted above, fusible elements, such as antifuses, are employed in integrated circuits, such as one-time programmable (OTP) devices, to permit changes in the configuration of the integrated circuits after fabrication. Initially fabricated as an open circuit, an antifuse comprises two conductive terminals separated by an insulator (e.g., a dielectric material). The antifuse is programmed by applying a relatively high voltage across its terminals to rupture the insulator and form an electrically conductive path between the terminals. A gate dielectric antifuse may be a metal-oxide-semiconductor field-effect transistor (MOSFET) that is designed such that the gate oxide located between the transistor's gate terminal and the body—or between the gate terminal and the source/drain terminal—breaks down (i.e., ruptures) after a sufficiently high voltage is applied.

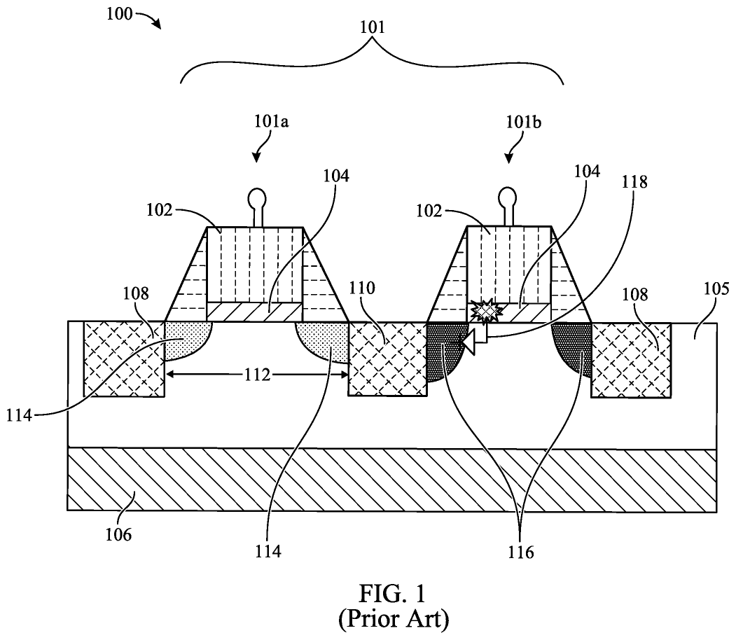

FIG. 1 illustrates a cross-sectional view of a one-time programmable (OTP) device 100. As illustrated, the OTP device 100 may include a plurality of transistor devices 101 (e.g., 101a, 101b), each including a gate region 102 formed above a dielectric layer 104 over a body structure 105 disposed above a substrate 106 (e.g., silicon). In some cases, the plurality of transistor devices 101 may correspond to different types of devices, such as core devices and input/output (I/O) devices. In certain cases, core devices may include low voltage transistors optimized for in-chip processing (e.g., core n-type metal-oxide-semiconductor (NMOS) and core p-type metal-oxide-semiconductor (PMOS) transistors) while I/O devices may include higher voltage devices (e.g., I/O NMOS and I/O PMOS transistors) optimized for inter-chip processing, usually located near the periphery of a structure of the OTP device 100. As illustrated, the transistor device 101a may correspond to a core device, such as a word line transistor device, while the transistor device 101b may correspond to an input/output (I/O) device, such as an antifuse transistor device.

In some cases, the gate region 102 may be composed of a material such as N-doped polycrystalline silicon. Additionally, in some cases, the dielectric layer 104 may be composed of a dielectric material, such as silicon dioxide (SiO₂), silicon nitride (Si₃N₄), or the like. As shown, the body structure 105 may be doped to form a source region 108 and a drain region 110. The body structure 105 may include a channel region 112 between the source region 108 and the drain region 110. It should be noted that the source region 108 and drain region 110 may be interchangeable and that the layout of the source region 108 and drain region 110 in FIG. 1 is not intended to be limiting. For example, in some cases the source region 108 may be the drain region 110 and vice versa.

In some cases, the source region 108 and the drain region 110 may be composed of a highly doped N-type or P-type material, depending on the material type of the body structure 105. For example, in some cases, when the body structure 105 is composed of a P-type material (also referred to as a “P-well”), the source region 108 and the drain region 110 may be composed of a highly doped N-type (N+) material and vice versa. Generally, highly doped regions are regions containing a higher concentration of P-type or N-type dopants than the rest of the body structure 105.

Further, as illustrated, the body structure 105 may also include pairs of lightly doped drain (LDD) extension regions implanted into the channel region 112. As their name implies, the LDD extension regions may be composed of a lightly doped semiconductor material, generally having a lower concentration of dopants compared to the source region 108 and the drain region 110.

As illustrated, the transistor device 101a (e.g., corresponding to a word line transistor device) may include LDD extension regions 114, and transistor device 101b (e.g., corresponding to an antifuse device) may include LDD extension regions 116. As illustrated, the LDD extension regions 114 may extend from source region 108 and drain region 110 inwards into the channel region 112 and partially underneath the gate region 102. In contrast, LDD extension regions 116 of the transistor device 101b may also extend from source region 108 and drain region 110 inwards into the channel region 112, but may not extend into a region underneath the gate region 102, for example, due to self-alignment during fabrication.

In certain cases, core devices (e.g., transistor device 101a) and I/O devices (e.g., transistor device 101b) may be implanted with different LDDs to control their respective short channel effects. For example, in some cases, the LDD extension regions 114 may be used in the transistor device 101a (e.g., a low voltage word line transistor device) to control a short-channel threshold voltage roll-off, whereas the LDD extension regions 116 may be used in the transistor device 101b (e.g., a high voltage antifuse transistor device) to improve channel hot carrier (CHC) reliability.

As noted above, the transistor device 101b may correspond to an antifuse device. An antifuse generally is initially fabricated as an open circuit and comprises two conductive terminals separated by an insulator (e.g., a dielectric material). The antifuse may be programmed by applying a high voltage across its terminals (e.g., a gate-to-source voltage (V_{g}s)) to rupture the insulator and form an electrically conductive path between the terminals.

For example, if the voltage across the dielectric layer 104 at any point along its thickness exceeds a breakdown voltage, VBD, then the dielectric layer 104 will break down (e.g., plasma channels may form), and a short circuit (or at least a path with low resistance) will be created through the dielectric layer 104. The breakdown may occur at one or more points along the dielectric layer 104 between the gate region 102 and the body structure 105 (or LDD extension regions 114 and 116) and/or between the gate region 102 and source region 108/drain region 110, thereby creating different types of conduction paths.

Once the antifuse has been programmed (i.e., the dielectric layer 104 has broken down), the amount of current flow from the gate region 102 to the source region 108/drain region 110 may be inversely proportional to the resistance of the conduction path(s) created. Sensing circuits (not shown) that read the logical state of the antifuse measure the current flow through the antifuse to determine whether the antifuse has been programmed. Little or no current flow (e.g., open circuit) through the antifuse means the antifuse has not been programmed, while substantial current flow (e.g., short circuit) means the antifuse has been programmed.

In certain cases, when breakdown of the dielectric layer 104 occurs (i.e., the antifuse has been programmed), a P-N junction 118 may be formed in the current read path between the body structure 105 (e.g., a P-well) and the LDD extension regions 116 (N-doped). The P-N junction 118, however, causes a forward voltage drop (e.g., 0.7 volts) during a read operation of the transistor device 101b, which degrades the read current and may lead to margin read yield loss.

### Example Improved Antifuse Device

Therefore, aspects of the present disclosure provide techniques for reducing or eliminating such voltage drop during read operations in an antifuse device. For example, in some cases, techniques presented herein involve introducing at least one set of LDD extension regions within an antifuse transistor device (e.g., such as transistor device 101b) such that when the antifuse transistor device is programmed (e.g., a gate oxide has broken down), an ohmic contact is formed between a gate region of the antifuse transistor device and at least one of a first active region or a second active region (the source and/or drain) of the antifuse device, removing the P-N junction in the read path and the associated voltage drop.

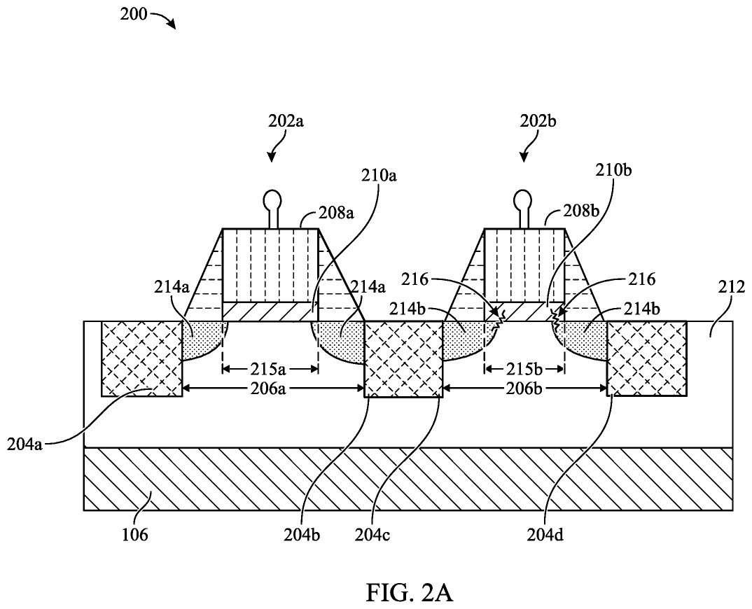

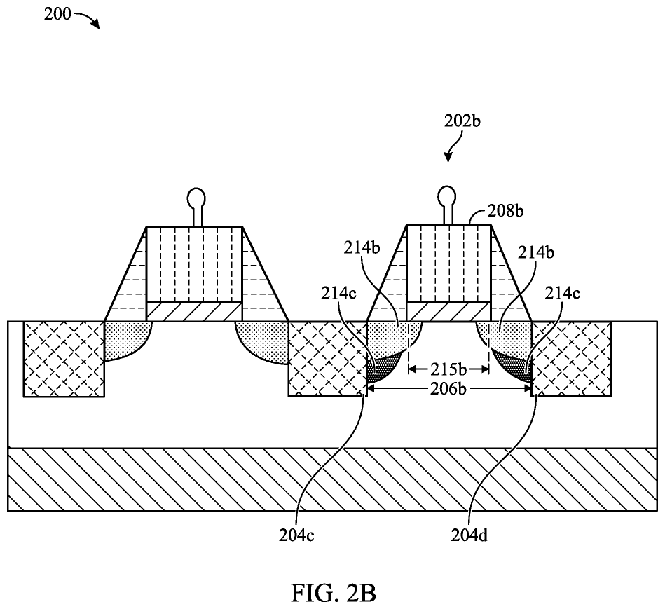

FIG. 2A illustrates an example cross-section of an OTP device 200, including a word line transistor device 202a and an antifuse transistor device 202b, according to certain aspects presented herein. As illustrated, the word line transistor device 202a may include a first active region 204a laterally spaced from a second active region 204b and may have a first channel region 206a disposed between the first active region 204a and the second active region 204b. Additionally as illustrated, the antifuse transistor device 202b may include a third active region 204c laterally spaced from a fourth active region 204d and may have a second channel region 206b disposed between the third active region 204c and the fourth active region 204d. In some cases, as illustrated, the second active region 204b and the third active region 204c may share the same active region. In other words, the second active region 204b may comprise the third active region 204c or vice versa. For other cases, the second active region 204 and the third active region 204c may be separate and distinct.

Additionally, as illustrated, the word line transistor device 202a may include a first gate region 208a disposed above a first dielectric layer 210a located above the first channel region 206a. Likewise, the antifuse transistor device 202b may include a second gate region 208b disposed above a second dielectric layer 210b located above the second channel region 206b. In some cases, the first gate region 208a and the second gate region 208b may be composed of a material such as N-doped or P-doped polycrystalline silicon. Additionally, the first dielectric layer 210a and the second dielectric layer 210b may be composed of a dielectric material, such as silicon dioxide (SiO₂), silicon nitride (Si₃N₄), or the like.

In some cases, the first active region 204a and the fourth active region 204d may comprise a source region, while the second active region 204b and the third active region 204c may comprise a drain region or vice versa. In some cases, the first active region 204a, the second active region 204b, the third active region 204c, and the fourth active region 204d may be composed of a highly doped N-type or P-type material, which may depend on the type of material used for a body structure 212, the first gate region 208a, and the second gate region 208b. For example, in some cases, when the body structure 212 is composed of a P-type material, the first active region 204a, the second active region 204b, the third active region 204c, the fourth active region 204d, the first gate region 208a, and the second gate region 208b may be composed of a highly doped N-type material and vice versa. In other words, the body structure 212 may comprise a doped material that is of an opposite type relative to the source region and the drain region. Generally, highly doped regions are regions containing a higher concentration of P-type or N-type dopants than the rest of the body structure 212.

Additionally, as illustrated, the first channel region 206a of the word line transistor device 202a may be implanted with a set of LDD extension regions 214a. Similarly, the second channel region 206b of the antifuse transistor device 202b may be implanted with a second set of LDD extension regions 214b. In some cases, the first set of LDD extension regions 214a of the word line transistor device 202a and the second set of LDD extension regions 214b of the antifuse transistor device 202b may comprise core LDD extension regions. Additionally, in some cases, the first set of LDD extension regions 214a and the second set of LDD extension regions 214b may have approximately the same dopant concentrations. For example, the first set of LDD extension regions 214 and the second set of LDD extension regions 214b may have been implanted with a dose between about 1E14 to 1E15 atoms/cm′.

As illustrated, the first set of LDD extension regions 214a may be formed (e.g., implanted) in the first channel region 206a and extend partially across the first channel region 206a from the first active region 204a and from the second active region 204b. Additionally, as illustrated, the first set of LDD extension regions 214a may extend partially into a first portion 215a of the first channel region 206a underneath the first gate region 208a.

Similarly, as illustrated, the second set of LDD extension regions 214b may be formed (e.g., implanted) in the second channel region 206b and extend partially across the second channel region 206b from the third active region 204c and the fourth active region 204d. To help alleviate the forward voltage drop issue described above with respect to FIG. 1, the second set of LDD extension regions 214b of the antifuse transistor device 202b of the OTP device 200 may be formed in the second channel region 206b and may extend partially into a second portion 215b of the second channel region 206b underneath the second gate region 208b such that an ohmic contact (rather than a P-N junction) is formed between the second gate region 208b and at least one of the third active region 204c or the fourth active region 204d when the antifuse transistor device is programmed.

For example, as noted above, if a voltage across the second dielectric layer 210b at any point along its thickness exceeds a breakdown voltage, VBD, then the second dielectric layer 210b will break down (e.g., plasma channels may form), and a short circuit (or at least a path with low resistance) will be created through the second dielectric layer 210b. According to aspects, since the second set of LDD extension regions 214b extend partially into the second portion 215b of the second channel region 206b underneath the second gate region 208b (e.g., as well as underneath the second dielectric layer 210b) and are the same doping type as the second gate region and the third and fourth active regions 204c, 204d, when breakdown of the second dielectric layer 210b occurs, a P-N junction is not formed (in contrast to FIG. 1). Rather, the second set of LDD extension regions 214b is in ohmic contact with the second gate region 208b, as illustrated at 216. This elimination of the P-N voltage drop in the read path increases the read current and improves read operation of the OTP device 200.

In some cases, the OTP device 200 may comprise a third set of LDD extension regions 214c, located in the antifuse transistor device 202b, as illustrated in FIG. 2B. Disposed underneath the second set of LDD extension regions 214b, the third set of LDD extension regions 214c may extend partially across the second channel region 206b from the third active region 204c and the fourth active region 204d. As illustrated, the third set of LDD extension regions 214c of the antifuse transistor device 202b do not extend into the second portion 215b of the second channel region 206b underneath the second gate region 208b. This may be due to a self-alignment process of the third set of LDD extension regions 214c.

In some cases, the second set of LDD extension regions 214b of the antifuse transistor device 202b and the third set of LDD extension regions 214c of the antifuse transistor device 202b comprise significantly different dopant concentrations. As used herein, “significantly different dopant concentrations” generally refers to dopant concentrations that are different by at least an order of magnitude. For example, the second set of LDD extension regions 214b may have been implanted with a dose between about 1E14 to 1E15 atoms/cm², whereas the third set of LDD extension regions 214c may have been implanted with a dose between about 1E13 to 1E14 atoms/cm². For example, in some cases, the third set of LDD extension regions 214c of the antifuse transistor device 202b comprise input/output LDD extension regions. Additionally, in some cases, the second set of LDD extension regions 214b of the antifuse transistor device 202b comprise core LDD extension regions, having a higher dopant concentration than the input/output LDD extension regions.

In some cases, the third set of LDD extension regions 214c may be formed in the second channel region 206b first, using a self-aligned process, and the second set of LDD extension regions 214b may be layered above (e.g., directly on top of) the third set of LDD extension regions 214c. According to aspects, by layering both types of LDD extension regions (e.g., core LDD and I/O LDD), a short-channel threshold voltage roll-off of the antifuse transistor device 202b may be controlled while also improving channel hot carrier (CHC) reliability and eliminating, or at least reducing, the voltage drop during a read operation associated with the antifuse transistor device 202b.

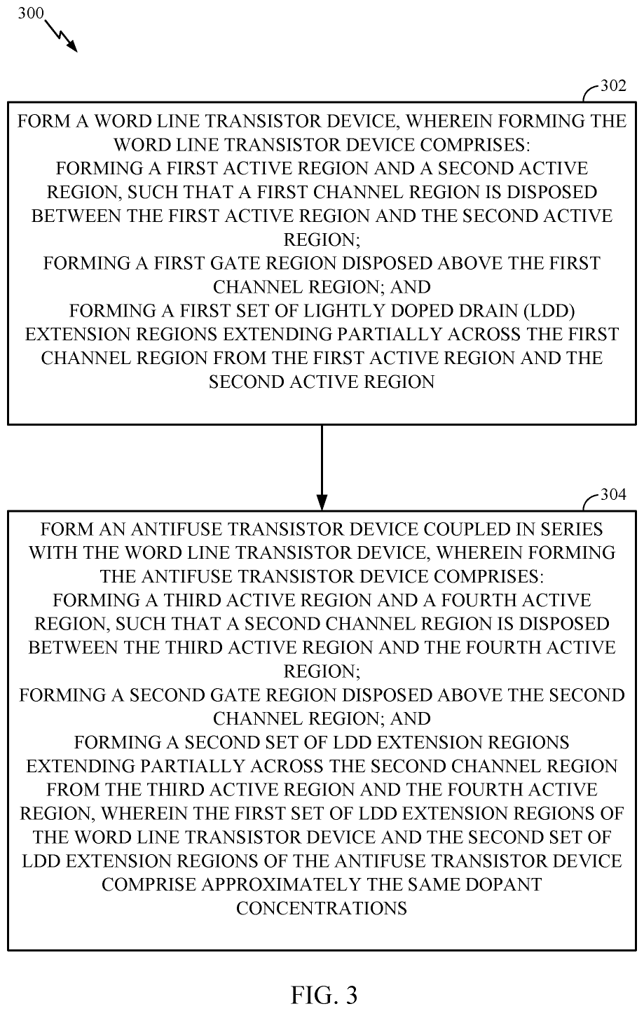

FIG. 3 is a flow diagram illustrating example operations 300 for fabricating an OTP device, in accordance with certain aspects of the present disclosure. The operations 300 may be performed, for example, by a semiconductor processing facility (e.g., a foundry).

The operations 300 begin, at block 302, with the semiconductor processing facility forming a word line transistor device. Forming the word line transistor device may include forming a first active region and a second active region, such that a first channel region is disposed between the first active region and the second active region, forming a first gate region disposed above the first channel region, and forming a first set of lightly doped drain (LDD) extension regions extending partially across the first channel region from the first active region and the second active region.

At block 304, the semiconductor processing facility forms an antifuse transistor device coupled in series with the word line transistor device. Forming the antifuse transistor device may involve forming a third active region and a fourth active region, such that a second channel region is disposed between the third active region and the fourth active region, forming a second gate region disposed above the second channel region, and forming a second set of LDD extension regions extending partially across the second channel region from the third active region and the fourth active region, wherein the first set of LDD extension regions of the word line transistor device and the second set of LDD extension regions of the antifuse transistor device comprise approximately the same dopant concentrations.

Additionally, in some cases, at least the second set of LDD extension regions of the antifuse transistor device extend partially into a portion of the second channel region underneath the second gate region of the antifuse transistor device.

Additionally, in some cases, forming the antifuse transistor device comprises forming a third set of LDD extension regions extending partially across the second channel region from the third active region and the fourth active region.

Additionally, in some cases, the third set of LDD extension regions of the antifuse transistor device do not extend into the portion of the second channel region underneath the second gate region of the antifuse transistor device.

Additionally, in some cases, the second set of LDD extension regions of the antifuse transistor device and the third set of LDD extension regions of the antifuse transistor device comprise significantly different dopant concentrations.

Additionally, in some cases, the first set of LDD extension regions of the word line transistor device and the second set of LDD extension regions of the antifuse transistor device comprise core LDD extension regions. Further, in some cases, the third set of LDD extension regions of the antifuse transistor device comprise input/output LDD extension regions. Further, in some cases, the core LDD extension regions have a higher dopant concentration than the input/output LDD extension regions.

Additionally, in some cases, forming the second set of LDD extension regions comprises forming the second set of LDD extension regions in the second channel region such that an ohmic contact is formed between the second gate region and at least one of the third active region or the fourth active region when the antifuse transistor device is programmed.

Additionally, in some cases, fabricating the OTP device may include forming a first dielectric layer disposed between the first gate region and the first channel region and forming a second dielectric layer disposed between the second gate region and the second channel region. In some cases, the first dielectric layer and the second dielectric layer comprise primarily silicon dioxide.

Additionally, in some cases, the first gate region and the second gate region comprise N-doped polycrystalline silicon. Additionally, in some cases, the first active region, the second active region, the third active region, and the fourth active region comprise one of a highly doped N-type material or a highly doped P-type material. Additionally, in some cases, the first channel region and the second channel region comprise a dopant type that is opposite to the first active region, the second active region, the third active region, and the fourth active region.

Additionally, in some cases, the second active region of the word line transistor device comprises the third active region of the antifuse transistor device.

Additionally, in some cases, the first set of LDD extension regions of the word line transistor device and the second set of LDD extension regions of the antifuse transistor device comprise core LDD extension regions.

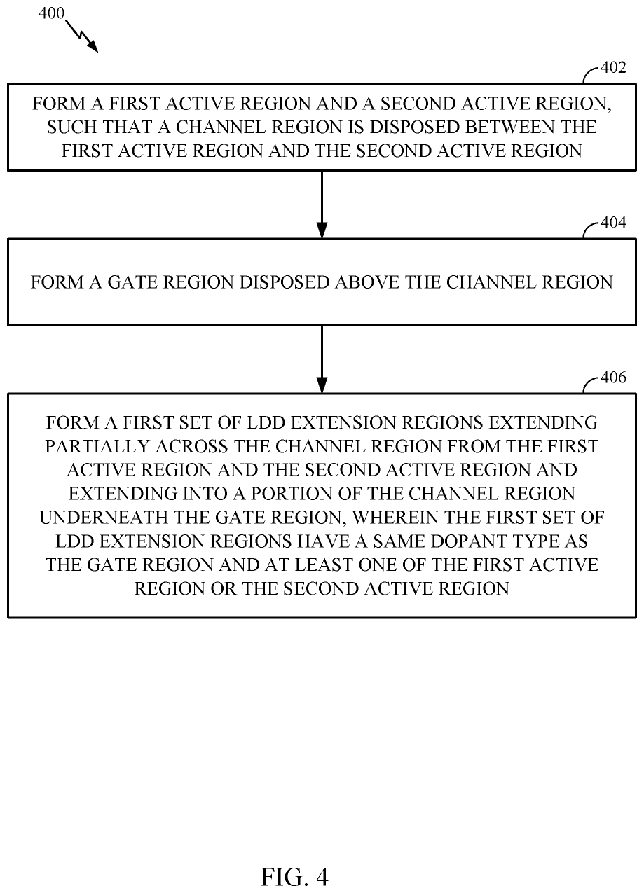

FIG. 4 is a flow diagram illustrating example operations 400 for fabricating an antifuse transistor device, in accordance with certain aspects of the present disclosure. The operations 400 may be performed, for example, by a semiconductor processing facility (e.g., a foundry).

The operations 400 begin, at block 402, with the semiconductor processing facility forming a first active region and a second active region, such that a channel region is disposed between the first active region and the second active region.

At block 404, the semiconductor processing facility forms a gate region disposed above the channel region.

At block 406, the semiconductor processing facility forms a first set of lightly doped drain (LDD) extension regions extending partially across the channel region from the first active region and the second active region and extending into a portion of the channel region underneath the gate region. The first set of LDD extension regions have a same dopant type as the gate region and at least one of the first active region or the second active region.

Additionally, in some cases, forming the first set of LDD extension regions comprises forming the first set of LDD extension regions in the channel region such that an ohmic contact is formed between the gate region and at least one of the first active region or the second active region when the antifuse transistor device is programmed.

Additionally, in some cases, fabricating the antifuse device further comprises forming a second set of LDD extension regions extending partially across the channel region from the first active region and the second active region. The first set of LDD extension regions and the second set of LDD extension regions comprise significantly different dopant concentrations.

Additionally, in some cases, the second set of LDD extension regions do not extend into the portion of the channel region underneath the gate region.

Additionally, in some cases, the first set of LDD extension regions comprise core LDD extension regions. Additionally, in some cases, the second set of LDD extension regions comprise input/output LDD extension regions. Additionally, in some cases, the core LDD extension regions have a higher dopant concentration than the input/output LDD extension regions.

Additionally, in some cases, fabricating the antifuse transistor device further comprises forming a dielectric layer disposed between the gate region and the channel region. Additionally, in some cases, the dielectric layer comprises primarily silicon dioxide. Additionally, in some cases, the gate region comprises N-doped polycrystalline silicon. Additionally, in some cases, the first active region and the second active region comprise one of a highly doped N-type material or a highly doped P-type material. Additionally, in some cases, the channel region comprises a dopant type that is opposite to the first active region and the second active region.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A one-time programmable (OTP) device comprising:
a word line transistor device comprising:
a first active region;
a second active region;
a first channel region disposed between the first active region and the second active region;
a first gate region disposed above the first channel region; and
a first set of lightly doped drain (LDD) extension regions extending partially across the first channel region from the first active region and the second active region; and
an antifuse transistor device coupled in series with the word line transistor device, the antifuse transistor device comprising:
a third active region;
a fourth active region;
a second channel region disposed between the third active region and the fourth active region;
a second gate region disposed above the second channel region; and
a second set of LDD extension regions extending partially across the second channel region from the third active region and the fourth active region, wherein the first set of LDD extension regions of the word line transistor device and the second set of LDD extension regions of the antifuse transistor device comprise approximately the same dopant concentrations.

2. The OTP device of claim 1, wherein at least the second set of LDD extension regions of the antifuse transistor device extend partially into a portion of the second channel region underneath the second gate region of the antifuse transistor device.

3. The OTP device of claim 2, wherein the antifuse transistor device further comprises a third set of LDD extension regions extending partially across the second channel region from the third active region and the fourth active region.

4. The OTP device of claim 3, wherein the third set of LDD extension regions of the antifuse transistor device do not extend into the portion of the second channel region underneath the second gate region of the antifuse transistor device.

5. The OTP device of claim 3, wherein the second set of LDD extension regions of the antifuse transistor device and the third set of LDD extension regions of the antifuse transistor device comprise significantly different dopant concentrations.

6. The OTP device of claim 5, wherein:
the first set of LDD extension regions of the word line transistor device and the second set of LDD extension regions of the antifuse transistor device comprise core LDD extension regions;
the third set of LDD extension regions of the antifuse transistor device comprise input/output LDD extension regions; and
the core LDD extension regions have a higher dopant concentration than the input/output LDD extension regions.

7. The OTP device of claim 1, wherein the second set of LDD extension regions are formed in the second channel region such that an ohmic contact is formed between the second gate region and at least one of the third active region or the fourth active region when the antifuse transistor device is programmed.

8. The OTP device of claim 1, wherein:
a first dielectric layer is disposed between the first gate region and the first channel region; and
a second dielectric layer is disposed between the second gate region and the second channel region.

9. The OTP device of claim 8, wherein the first dielectric layer and the second dielectric layer comprise primarily silicon dioxide.

10. The OTP device of claim 1, wherein the first gate region and the second gate region comprise N-doped polycrystalline silicon.

11. The OTP device of claim 1, wherein the first active region, the second active region, the third active region, and the fourth active region comprise one of a highly doped N-type material or a highly doped P-type material.

12. The OTP device of claim 11, wherein the first channel region and the second channel region comprise a dopant type that is opposite to the first active region, the second active region, the third active region, and the fourth active region.

13. The OTP device of claim 1, wherein the second active region of the word line transistor device comprises the third active region of the antifuse transistor device.

14. The OTP device of claim 1, wherein the first set of LDD extension regions of the word line transistor device and the second set of LDD extension regions of the antifuse transistor device comprise core LDD extension regions.

15. An antifuse transistor device comprising:
a first active region;
a second active region;
a channel region disposed between the first active region and the second active region;
a gate region disposed above the channel region; and
a first set of lightly doped drain (LDD) extension regions extending partially across the channel region from the first active region and the second active region and extending into a portion of the channel region underneath the gate region, wherein the first set of LDD extension regions have a same dopant type as the gate region and at least one of the first active region or the second active region.

16. The antifuse transistor device of claim 15, wherein the first set of LDD extension regions are formed in the channel region such that an ohmic contact is formed between the gate region and at least one of the first active region or the second active region when the antifuse transistor device is programmed.

17. The antifuse transistor device of claim 15, further comprising a second set of LDD extension regions extending partially across the channel region from the first active region and the second active region, wherein:
the first set of LDD extension regions and the second set of LDD extension regions comprise significantly different dopant concentrations; and
the second set of LDD extension regions do not extend into the portion of the channel region underneath the gate region.

18. The antifuse transistor device of claim 15, further comprising a second set of LDD extension regions extending partially across the channel region from the first active region and the second active region, wherein:
the first set of LDD extension regions and the second set of LDD extension regions comprise significantly different dopant concentrations;
the first set of LDD extension regions comprise core LDD extension regions;
the second set of LDD extension regions comprise input/output LDD extension regions; and
the core LDD extension regions have a higher dopant concentration than the input/output LDD extension regions.

19. The antifuse transistor device of claim 15, wherein:
the first active region and the second active region comprise one of a highly doped N-type material or a highly doped P-type material; and
the channel region comprises a dopant type that is opposite to the first active region and the second active region.

20. A method for fabricating a one-time programmable (OTP) device comprising:
forming a word line transistor device, wherein forming the word line transistor device comprises:
forming a first active region and a second active region, such that a first channel region is disposed between the first active region and the second active region;
forming a first gate region disposed above the first channel region; and
forming a first set of lightly doped drain (LDD) extension regions extending partially across the first channel region from the first active region and the second active region; and
forming an antifuse transistor device coupled in series with the word line transistor device, wherein forming the antifuse transistor device comprises:
forming a third active region and a fourth active region, such that a second channel region is disposed between the third active region and the fourth active region;
forming a second gate region disposed above the second channel region; and
forming a second set of LDD extension regions extending partially across the second channel region from the third active region and the fourth active region, wherein the first set of LDD extension regions of the word line transistor device and the second set of LDD extension regions of the antifuse transistor device comprise approximately the same dopant concentrations.
